(19) United States
(12) Patent Application Publication
(10) Pub. No.: US 2004/0089929 A1
(43) Pub. Date: May 13, 2004

(54) Semiconductor package structure and method for manufacturing the same

(75) Inventors: Chi-Tsung Chiu, Kaohsiung (TW); Su Tao, Kaohsiung (TW); Sung-Mao Wu, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaohsiung (TW)

(21) Appl. No.: 10/463,510

(22) Filed: Jun. 18, 2003

(30) Foreign Application Priority Data
Nov. 13, 2002 (TW) 091133272

(51) Int. Cl. H01L 23/02

(52) U.S. Cl. 257/678

(57) ABSTRACT

A semiconductor package structure includes a substrate, a semiconductor die, a plurality of wires, and a molding compound. In this case, the semiconductor die is attached to the substrate. Each of the wires respectively has a center conductive layer, a dielectric layer, and a metal layer. Each of the center conductive layers connects the semiconductor die to the substrate. Each of the dielectric layers covers each of the center conductive layers, and the metal layers cover the dielectric layers. The molding compound encapsulates the semiconductor die and the wires. This invention also provides another semiconductor package structure, including a substrate, a semiconductor die, a plurality of wires, and a conductive molding compound. Each of the wires respectively has a center conductive layer and a dielectric layer. The conductive molding compound is made of a conductive material. Furthermore, the invention also provides a method for manufacturing the semiconductor package structure.

### BACKGROUND OF THE INVENTION

1. Field of Invention

The invention relates to a semiconductor package structure and method for manufacturing the same, and in particular, to a semiconductor package structure having bonding wires and method for manufacturing the same.

2. Related Art

Since semiconductor devices work with high-speed signal transmission, are highly integrated and have become more compact, the number of I/O pins in a semiconductor package has increased. Therefore, the pitches between the wires of a semiconductor package are tighter, and consequently short circuits occur. Additionally, signal transmission frequency is greatly increased, undesirable mutual capacitance and inductance are caused by EMI, and noise occurs during signal transmission, resulting in increased power loss and excessive heat.

To solve the previously mentioned problems, those skilled in the art coat a dielectric layer over the wires. As shown in FIG. 1, a conventional semiconductor package structure 1 includes a substrate 10, a semiconductor die 11, a plurality of wires 12, and a molding compound 13. Each of the wires 12 has a center conductive layer 121 and a dielectric layer 122, which is used for insulating each center conductive layers 121. Therefore, short circuits between the wires 12 are prevented. Furthermore, the dielectric layer 122 can also reduce the EMI effect, so that undesirable mutual capacitance and inductance during signal transmission is reduced.

In practice, the dielectric layer 122, however, cannot completely prevent electromagnetic waves. Thus, the EMI effect still occurs and generates the mentioned noise problem. Moreover, the impedance of wires 12 is approximately 200 ohms, so signal transmission quality suffers due to the high impedance effect of the wires 12.

In view of the foregoing problems of the conventional semiconductor package structure, there is a need in the semiconductor arts for reduction of undesirable mutual capacitance and inductance caused by EMI, preventing noise interference and efficiently reducing the impedance of the wires.

### SUMMARY OF THE INVENTION

In view of the above-mentioned problems, an objective of the invention is to provide a semiconductor package structure and a method for manufacturing the same, which can prevent noise caused by EMI.

It is another objective of the invention to provide a semiconductor package structure and method for manufacturing the same, which can efficiently reduce impedance of the wires.

To achieve the above-mentioned objective, a semiconductor package structure of the invention includes a substrate, a semiconductor die, a plurality of wires, and a molding compound. In the invention, the semiconductor die is provided on the substrate. Each of the wires has a center conductive layer, a dielectric layer and a metal layer. The center conductive layers respectively connect the semiconductor die to the substrate. Each of the dielectric layers covers each of the center conductor layers, and each of the metal layers covers- each of the dielectric layers. The molding compound encapsulates the semiconductor die and the wires.

Furthermore, the invention also discloses another semiconductor package structure, which includes a substrate, a semiconductor die, a plurality of wires, and a conductive molding compound. In this case, the semiconductor die is provided on the substrate. Each of the wires has a center conductive layer connecting the semiconductor die to the substrate and a dielectric layer covering the center conductive layer. The conductive molding compound, which is made of conductive materials, encapsulates the semiconductor die and wires.

Moreover, the invention further discloses a method for manufacturing a semiconductor package structure. The method includes steps of providing a semiconductor die on a substrate, forming a plurality of center conductive layers connecting the substrate to the semiconductor die, forming a plurality of dielectric layers covering the center conductive layers, forming a plurality of metal layers covering the dielectric layers, and forming a molding compound encapsulating the semiconductor die and the metal layers.

As mentioned above, since the semiconductor package structure and method for manufacturing the same according to the invention employ the metal layers or the conductive molding compound to cover the dielectric layers, the metal layers or the conductive molding compound generate a shielding effect to reflect EMI transmission through the dielectric layers. Thus, undesirable mutual capacitance and inductance of the wires caused by EMI would not occur, and noise interference is efficiently prevented. In addition, since the dielectric layers are covered with metal layers or conductive molding compound, the wires of the invention function as coaxial cables. Thus, the impedance of wires is efficiently reduced.

### BRIEF DESCRIPTION OF THE DRAWINGS

The invention will become more fully understood from the detailed description given herein below illustrations only, and thus are not limitative of the present invention, and wherein:

FIG. 1 is a schematic illustration showing a conventional semiconductor package structure;

FIG. 2 is a schematic illustration showing a semiconductor package structure according to a preferred embodiment of the invention, wherein each of the wires has a center conductive layer, a dielectric layer and a metal layer;

FIG. 3 is a schematic illustration showing a semiconductor package structure according to another preferred embodiment of the invention, wherein each of the wires has a center conductive layer and a dielectric layer;

FIG. 4 is a flow chart showing the procedure of a method for manufacturing a semiconductor package structure according to a preferred embodiment of the invention; and

FIG. 5 is a flow chart showing the procedure of a method for manufacturing a semiconductor package structure according to another preferred embodiment of the invention.

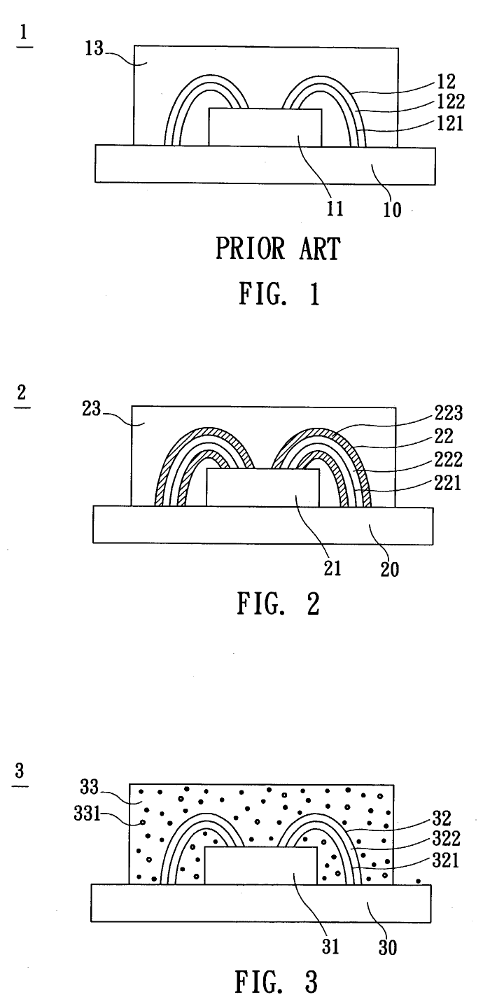

### DETAILED DESCRIPTION OF THE INVENTION

The semiconductor package structure and method for manufacturing the same according to the preferred embodiments of the invention will be described herein below with reference to the accompanying drawings, wherein the same reference numbers refer to the same elements.

With reference to FIG. 2, a semiconductor package structure 2 includes a substrate 20, a semiconductor die 21, a plurality of wires 22, and a molding compound 23.

The semiconductor die 21 is formed on the substrate 20. In the present embodiment, the semiconductor die 21 is attached to the substrate 20 with any conventional adhesive such as a polymer epoxy, a black epoxy or a silver paste.

Each of the wires 22 includes a center conductive layer 221, a dielectric layer 222 and a metal layer 223. The center conductive layers 221 respectively connect the semiconductor die 21 to the substrate 20. Each of the dielectric layers 222 covers each of the center conductive layers 221, and each of the metal layers 223 covers each of the dielectric layers 222. In this embodiment, the center conductive layers 221 are typically made of a conductive material such as gold, and are formed with a conventional wire bonding technique. The dielectric layers 222 are made of any dielectric material such as SiO₂. The substrate 20 may include a ground plan (not shown) and the metal layers 223 may further electrically connect to the ground plan, so as to enhance the ground shielding effect and impedance controlling ability of the wires 22.

The molding compound 23 is formed to encapsulate the semiconductor die 21 and wires 22. In the current embodiment, the molding compound 23 is made of any conventional molding material such as epoxy.

As shown in FIG. 2, the center conductive layers 221 of the embodiment are covered with the dielectric layers 222, respectively, so that the dielectric layers 222 isolate the center conductive layers 221 from each other. Thus, the short circuit of the wires 22 can be prevented, and the dielectric layers 222 further reduce the EMI effect of the wires 22. Furthermore, the ground shielding effect caused by the metal layers 223, which cover the dielectric layers, prevents the EMI interference. It should be noted that the structure of the wires 22 is similar to coaxial cables. Therefore, when the dielectric layers 222 are provided with proper thickness, the impedance of the wires 22, like coaxial cables, is approximately controlled between 50-75 ohms.

Referring to FIG. 3, a semiconductor package structure 3 according to another preferred embodiment of the invention includes a substrate 30, a semiconductor die 31, a plurality of wires 32 and a molding compound 33. In this embodiment, each of the wires 32 has a center conductive layer 321 connecting the semiconductor die 31 to the substrate 30, and a dielectric layer 322 covering the center conductive layer 321.

The molding compound 33 is made of a conductive material. In the current embodiment, a plurality of metal particles are distributed in the molding compound 33, so the molding compound 33 is electrically conductive. In addition, the substrate 30 includes a ground plan (not shown), and the molding compound 33 is electrically connected to the ground plan. People skilled in the art should know that the semiconductor package structure 3 is similarly capable of completely preventing EMI interference and reducing the impedance of the wires 32.

It should be noted that since the molding compound 33 is made of a conductive material, the heat dissipation efficiency of the molding compound 33 is better than that of a molding compound made of non-conductive materials. As a result, it facilitates the heat dissipation of the semiconductor package structure 3.

A method 4 for manufacturing the semiconductor package structure of the current invention is described in greater detail with reference to the following embodiment.

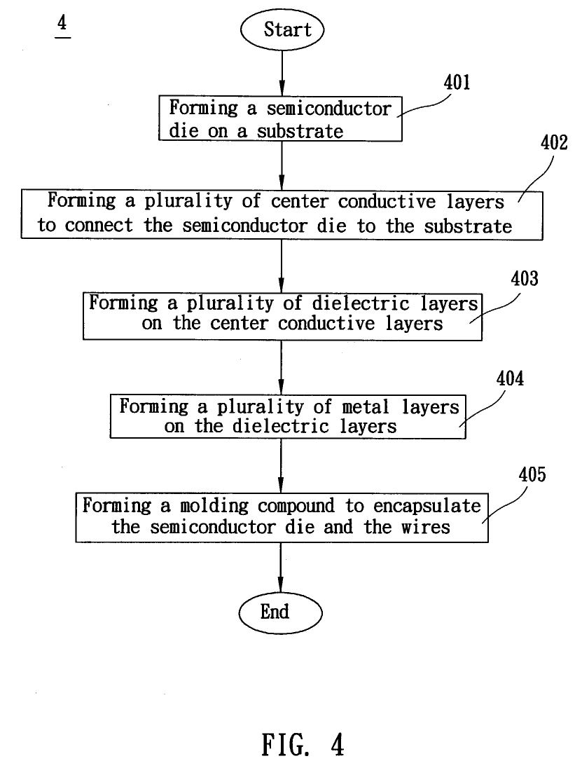

Referring to FIG. 4, in step 401, a semiconductor die is provided on a substrate. In this embodiment, an adhesive is applied to the substrate directly, and the semiconductor die is then mounted to the substrate. It should be noted that the adhesive can be applied in this step by a rotogravure or rotary silkscreen process.

Next, step 402 forms a plurality of center conductive layers to connect the semiconductor die to the substrate. In the present embodiment, the center conductive layers are formed with a conventional wire bonding technique, and are typically made of a conductive material such as gold.

In step 403, a plurality of dielectric layers are formed on the center conductive layers, respectively. In this case, a conventional PECVD process is employed to coat the dielectric layers over the center conductive layers.

After formation of the dielectric layers, a plurality of metal layers are formed on each of the dielectric layers, respectively, in step 404. Moreover, the substrate may include a ground plan such as a ground pad, and each of the metal layers further connects to the ground plan. Therefore, the metal layers are grounded with the ground plan. In the present embodiment, each wire of a semiconductor package structure of the invention has the center conductive layer, the dielectric layer and the metal layer.

Finally, step 405 forms a molding compound to encapsulate the semiconductor die and the wires. In the current embodiment, any conventional molding process can be used to form the molding compound. In brief, the substrate mounted with the semiconductor die and wires is positioned in a molding device in advance. The molding compound material is then melted and injected into the molding device. The molding compound material is then cooled and cured so as to form the desired molding compound.

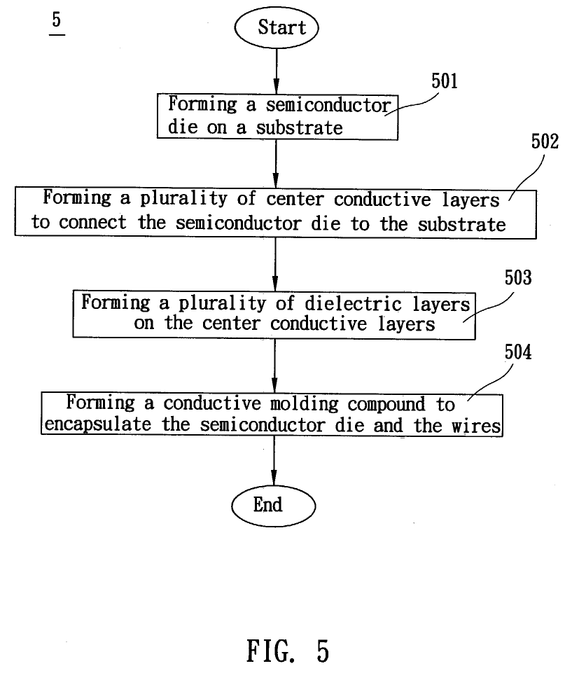

The invention further provides a method 5 for manufacturing a semiconductor package structure according to another preferred embodiment of the invention, which is used to manufacture the mentioned semiconductor package structure 3. Referring to FIG. 5, in step 501, a semiconductor die is provided on a substrate. In this embodiment, an adhesive is directly applied to the substrate, and the semiconductor die is then mounted to the substrate. In addition, the adhesive can be applied in this step using a conventional rotogravure or rotary silkscreen process.

Then, in step 502, a plurality of center conductive layers is formed to connect the semiconductor die to the substrate. In this embodiment, the center conductive layers are formed with a conventional wire bonding technique, and are typically made of a conductive material such as gold.

In step 503, a plurality of dielectric layers are formed on the center conductive layers, respectively, wherein a deposition process, such as a conventional PECVD process, is employed to coat the dielectric layers over the center conductive layers. In the current embodiment, each wire of the invention has the center conductive layer and the dielectric layer.

Finally, in step 504, a molding compound is formed to encapsulate the semiconductor die and the wires. In the current embodiment, the molding compound is made of a conductive material. For example, the majority of the molding compound is composed of epoxy, and includes a plurality of metal particles such as silver beads. The metal particles are distributed in the epoxy. Thus, the molding compound of the invention functions as a conductor. Moreover, the substrate may include a ground plan such as a ground pad, and the molding compound may further electrically connect to the ground plan. As mentioned above, the molding compound can be formed by utilizing any conventional molding process. Above all, the substrate mounted with the semiconductor die and wires is positioned in a molding device. The molding compound material with conductive metal particles is then melted and injected into the molding device. After that, the molding compound material is cooled and cured so as to form the conductive molding compound for encapsulating the substrate, semiconductor die and wires.

As mentioned above, since the semiconductor package structure and method for manufacturing the same of the preferred embodiments provide the metal layers or conductive molding compound to cover the dielectric layers, EMI interference between the wires is eliminated so as to prevent the undesirable mutual capacitance and inductance. Accordingly, noise interference is efficiently prevented. In addition, since the dielectric layers are covered with the metal layers or conductive molding compound, the impedance of the wires is efficiently reduced. Thus, signal transmission quality is improved, and the semiconductor package structure has improved reliability.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A semiconductor package structure, comprising:
a substrate;
a semiconductor die attached to the substrate;
a plurality of wires, each of the wires having a center conductive layer connecting the substrate to the semiconductor die, a dielectric layer covering the center conductive layer and a metal layer covering the dielectric layer; and
a molding compound encapsulating the semiconductor die and the wires.

2. The semiconductor package structure of claim 1, wherein the substrate further comprises a ground plan electrically connecting to the metal layer.

3. A semiconductor package structure, comprising:
a substrate;
a semiconductor die attached to the substrate;
a plurality of wires, each of the wires having a center conductive layer connecting the substrate to the semiconductor die and a dielectric layer covering the center conductive layer; and
a conductive molding compound encapsulating the semiconductor die and the wares.

4. The semiconductor package structure of claim 3, wherein the substrate further comprises a ground plan electrically connecting to the conductive molding compound.

5. A method for manufacturing a semiconductor package structure, comprising:
providing a semiconductor die on a substrate;
forming a plurality of center conductive layers to connect the substrate to the semiconductor die;
forming a plurality of dielectric layers to cover the center conductive layers;
forming a plurality of metal layers to cover the dielectric layers; and
forming a molding compound to encapsulate the semiconductor die and the metal layers.

6. The method of claim 5, wherein the substrate comprises a ground plan, the method further comprising:
electrically connecting the metal layers to the ground plan.
